(19) United States
(12) Patent Application Publication
(10) Pub. No.: US 2014/0151683 A1
(43) Pub. Date: Jun. 5, 2014

(54) THIN FILM TRANSISTOR

(71) Applicant: SAMSUNG DISPLAY CO., LTD., Yongin-City (KR)

(72) Inventors: Sang Ho Park, Suwon-si (KR); Su-Hyoung Kang, Bucheon-si (KR); Yoon Ho Khang, Yongin-si (KR); Dong Jo Kim, Yongin-si (KR); Joon Yong Park, Gunpo-si (KR); Sang Won Shin, Yongin-si (KR); Dong Hwan Shim, Yongin-si (KR)

(73) Assignee: Samsung Display Co., Ltd., Yongin-City (KR)

(21) Appl. No.: 13/873,426

(22) Filed: Apr. 30, 2013

(30) Foreign Application Priority Data
Dec. 5, 2012 (KR) 10-2012-0140477

(51) Int. Cl. H01L 29/786

(52) U.S. Cl. CPC H01L 29/7869
USPC 257/43

(57) ABSTRACT

A thin film transistor includes an oxide semiconductor, in which an oxygen defect content of the oxide semiconductor is no greater than about 0.15 based on an entire oxygen content included in the oxide semiconductor.

### CROSS-REFERENCE TO RELATED APPLICATION

This application claims priority to Korean Patent Application No. 10-2012-0140477, filed on Dec. 5, 2012, the disclosure of which is hereby incorporated herein by reference herein in its entirety.

### TECHNICAL FIELD

The present disclosure relates to a thin film transistor.

### DISCUSSION OF THE RELATED ART

A flat panel display, such as, for example, a liquid crystal display (LCD), an organic light emitting diode display (OLED display), an electrophoretic display, and a plasma display, includes multiple pairs of electric field generating electrodes and electro-optical active layers interposed therebetween. A liquid crystal display may include a liquid crystal layer as an electro-optical active layer, and an organic light emitting diode display may include an organic light emitting layer as an electro-optical active layer. One of a pair of electric field generating electrodes is generally connected to a switching device to receive an electrical signal, and the electro-optical active layer converts the electrical signal to an optical signal to display an image.

A flat panel display may include a display panel on which a thin film transistor is formed. Multi-layered electrodes, semiconductors, and the like are patterned on the thin film transistor display panel, and a mask is generally used for a patterning process.

In the meantime, a semiconductor is a significant factor for determining a characteristic of a thin film transistor. Amorphous silicon is commonly used for forming the semiconductor, but amorphous silicon may have low charge mobility, thereby having a limitation in manufacturing a high-performance thin film transistor. Further, when polysilicon is used, the charge mobility may be high, so that it may be relatively easy to manufacture a high-performance thin film transistor. However, the cost of polysilicon maybe high and uniformity of polysilicon may be low, so that there may be a limitation in manufacturing a large thin film transistor display panel.

Accordingly, research on a thin film transistor using an oxide semiconductor having higher charge mobility and a high ON/OFF ratio of current compared to amorphous silicon, and a lower cost and high uniformity compared to polysilicon has been conducted.

Particularly, to apply an oxide semiconductor to a thin film transistor, it is significant to increase charge mobility and reliability.

### SUMMARY

Exemplary embodiments of the present invention have been made in an effort to provide a thin film transistor having excellent reliability.

An exemplary embodiment of the present invention provides a thin film transistor, including: an oxide semiconductor, in which an oxygen defect content of the oxide semiconductor is no greater than about 0.15 based on an entire oxygen content included in the oxide semiconductor.

A ratio of oxygen content to the oxygen defect content in the oxide semiconductor may be quantified by measuring binding energy of an 1s orbital of oxygen.

The oxide semiconductor may include at least one of zinc oxide, zinc-tin oxide, zinc-indium oxide, indium oxide, titanium oxide, indium-gallium-zinc oxide, and indium-zinc-tin oxide.

The thin film transistor may further include: a substrate, a gate electrode disposed on the substrate, a source electrode disposed on the substrate and a drain electrode disposed on a same layer as that of the source electrode, and facing the source electrode. The oxide semiconductor is disposed between the gate electrode and the source electrode, or between the gate electrode and the drain electrode.

The gate electrode may be disposed under the oxide semiconductor, and the source electrode and the drain electrode may be disposed on the oxide semiconductor.

The thin film transistor may further include an etching preventing layer covering a channel portion of the oxide semiconductor, and overlapping edges of side surfaces of the source electrode and the drain electrode facing each other.

The thin film transistor may further include an insulation layer disposed on the source electrode and the drain electrode, and covering an exposed upper surface of the etching preventing layer between the source electrode and the drain electrode.

The etching preventing layer may be formed of at least one of a silicon-based oxide or a nitride.

The insulating layer may include at least one of silicon oxide (SiOx), silicon nitride (SiNx), and silicon oxynitride (SiONx).

The gate electrode may be disposed on the oxide semiconductor, and the source electrode and the drain electrode may be disposed under the oxide semiconductor.

The thin film transistor may further include an etching preventing layer disposed directly on a channel portion of the oxide semiconductor, wherein a portion of the etching preventing layer is exposed by the source electrode and the drain electrode spaced apart from the source electrode, and wherein the etching preventing layer is in direct physical contact with edges of the source electrode and the drain electrode; and a passivation layer disposed directly on the source electrode, the drain electrode and the portion of the etching preventing layer exposed by the source electrode and the drain electrode.

An exemplary embodiment of the present invention provides a thin film transistor including an oxide semiconductor, in which a tail state in an interface trap at a vicinity of a conduction band of the oxide semiconductor is no greater than about 10²¹ cm⁻³eV⁻¹, and a deep state in the interface trap at the vicinity of the conduction band of the oxide semiconductor is no greater than about 10¹⁸ cm⁻³eV⁻¹.

The oxide semiconductor may include at least one of zinc oxide, zinc-tin oxide, zinc-indium oxide, indium oxide, titanium oxide, indium-gallium-zinc oxide, and indium-zinc-tin oxide.

The thin film transistor may further include: a gate electrode, a source electrode, and a drain electrode disposed on a same layer as that of the source electrode, and facing the source electrode. The oxide semiconductor is disposed between the gate electrode and the source electrode, or between the gate electrode and the drain electrode.

The gate electrode may be disposed under the oxide semiconductor, and the source electrode and the drain electrode may be disposed on the oxide semiconductor.

The thin film transistor may further include an etching preventing layer covering a channel portion of the oxide semiconductor, and overlapping edges of side surfaces of the source electrode and the drain electrode facing each other.

The thin film transistor may further include an insulation layer disposed on the source electrode and the drain electrode, and covering an exposed upper surface of the etching preventing layer between the source electrode and the drain electrode.

The etching preventing layer may be formed of at least one of a silicon-based oxide or a nitride.

The gate electrode may be disposed on the oxide semiconductor, and the source electrode and the drain electrode may be disposed under the oxide semiconductor.

The thin film transistor may further include an etching preventing layer disposed directly on a channel portion of the oxide semiconductor, wherein a portion of the etching preventing layer is exposed by the source electrode and the drain electrode spaced apart from the source electrode, and wherein the etching preventing layer is in direct physical contact with edges of the source electrode and the drain electrode; and a passivation layer disposed directly on the source electrode, the drain electrode and the portion of the etching preventing layer exposed by the source electrode and the drain electrode.

According to the exemplary embodiments of the present invention, it is possible to implement a thin film transistor having high reliability by controlling a defect of oxygen included in an oxide semiconductor.

### BRIEF DESCRIPTION OF THE DRAWINGS

Exemplary embodiments of the present invention can be understood in more detail from the following detailed description taken in conjunction with the attached drawings in which:

FIG. 1 is a cross-sectional view illustrating a thin film transistor according to an exemplary embodiment of the present invention.

FIG. 2 is O1s orbital spectra of X-ray photoelectron spectroscopy (XPS) obtained by measuring oxygen content and oxygen defect content included in an oxide semiconductor.

FIG. 3 is a graph of measurement values of positive bias temperature stress (PBTS) according to an oxygen binding ratio, and FIG. 4 is a graph of measurement values of negative bias temperature stress (NBTS) according to an oxygen binding ratio.

FIG. 5 is a graph illustrating a change in oxygen defect content included in an oxide semiconductor thin film according to partial pressure of oxygen during a sputtering process.

FIG. 6 is a graph illustrating charge mobility of a thin film transistor including an oxide semiconductor according to partial pressure of oxygen during a sputtering process.

FIG. 7 is a graph illustrating a change in a density of state (DOS) within an oxide semiconductor according to partial pressure of oxygen during a sputtering process.

FIG. 8 is a graph of measurement values of positive bias temperature stress according to a tail state.

FIG. 9 is a cross-sectional view illustrating a thin film transistor according to an exemplary embodiment of the present invention.

FIG. 10 is a cross-sectional view illustrating a thin film transistor according to an exemplary embodiment of the present invention.

### DETAILED DESCRIPTION OF EXEMPLARY EMBODIMENTS

Hereinafter, exemplary embodiments of the present invention will be described in detail with reference to the accompanying drawings.

In the drawings, the thickness of layers, films, panels, regions, etc., may be exaggerated for clarity. It will be understood that when a layer is referred to as being “on” another layer or substrate, it can be directly on the other layer or substrate, or an intervening layer(s) may also be present. Like reference numerals designate like elements throughout the specification.

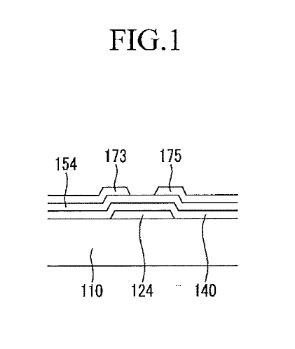

FIG. 1 is a cross-sectional view illustrating a thin film transistor according to an exemplary embodiment of the present invention.

Referring to FIG. 1, a gate electrode 124 is positioned on a substrate 110. The substrate 110 may be an insulation substrate, and may include, for example, plastic, glass, quartz or the like. Further, in an exemplary embodiment, the glass may include, for example, tempered glass. In an exemplary embodiment, the substrate 110 may be formed of, for example, one of polycarbonate (PC), polyester (PET), polypropylene (PP), polyethylene (PE) and polymethyl methacrylate (PMMA).

The gate electrode 124 may include, for example, an aluminum-based metal, such as aluminum (Al) or an aluminum alloy, a silver-based metal, such as silver (Ag) or a silver alloy, a copper-based metal, such as copper (Cu) or a copper alloy including copper manganese (CuMn), a molybdenum-based metal, such as molybdenum (Mo) or a molybdenum alloy, chromium (Cr), tantalum (Ta), tungsten (W) and titanium (Ti). Otherwise, the gate electrode 124 may also include, for example, a transparent conductive material, such as indium tin oxide (ITO), indium zinc oxide (IZO), aluminum doped ZnO (AZO), cadmium zinc oxide (CZO), indium gallium zinc oxide (IGZO), another suitable material, or a combination of the above.

In the present exemplary embodiment, it is described that the gate electrode 124 is formed as a single layer, but the gate electrode 124 is not limited thereto. For example, alternatively, in an exemplary embodiment, the gate electrode 124 may be formed in the form of a dual layer or a triple layer.

For example, when the gate electrode 124 has a dual layer structure, the gate electrode 124 may be formed of a lower layer and an upper layer, and the lower layer may be formed of one selected from a molybdenum-based metal, such as molybdenum (Mo) and a molybdenum alloy, chromium (Cr), a chromium alloy, titanium (Ti), a titanium alloy, tantalum (Ta), and a tantalum alloy, manganese (Mn), and a manganese alloy. The upper layer may be formed of, for example, one selected from an aluminum-based metal, such as aluminum (Al) and an aluminum alloy, a silver-based metal, such as silver (Ag) and a silver alloy, a copper-based metal, such as copper (Cu) and a copper alloy. When the gate electrode 124 has a triple layer structure, the gate electrode 124 may be formed by, for example, combining layers having different physical properties.

A gate insulating layer 140 is positioned on the gate electrode 124. The gate insulating layer 140 may include, for example, silicon nitride (SiNx), silicon oxide (SiOx), silicon oxynitride (SiONx), aluminum oxide (Al₂O₃), zirconium oxide (ZrO₂), hafnium oxide (HfO₂), titanium oxide (TiO₂), tantalum oxide (Ta₂O₅), a barium-strontium-titanium-oxygen (Ba—Sr—Ti—O) compound, a bismuth-zinc-niobium-oxygen (Bi—Zn—Nb—O) compound, an organic insulating material (e.g. benzocyclobutene (BCB)), and the like. The gate insulating layer 140 may have a multi-layer structure including two or more insulating layers (not illustrated). For example, an upper layer of the gate insulating layer 140 may be formed of SiOx and a lower layer of the gate insulating layer 140 may be formed of SiNx, or the upper layer may be formed of SiOx and the lower layer may be formed of SiON. When the gate insulating layer 140 contacting an oxide semiconductor 154 includes oxide, it is possible to prevent degradation of a channel layer.

The oxide semiconductor 154 is positioned on the gate insulating layer 140.

The oxide semiconductor 154 according to the present exemplary embodiment includes, for example, at least one of zinc oxide, zinc-tin oxide, zinc-indium oxide, indium oxide, titanium oxide, indium-gallium-zinc oxide, and indium-zinc-tin oxide. In this case, a ratio of oxygen defect to oxygen content included in the oxide semiconductor is no greater than about 0.15. Otherwise, a tail state for oxygen included in the oxide semiconductor may be no greater than about 10¹⁹ cm⁻³eV⁻¹, or a deep state may be no greater than about 10¹⁸ cm⁻³eV⁻¹. In addition, a source electrode 173 and a drain electrode 175 are spaced apart from each other and face each other on the oxide semiconductor 154. The source electrode 173 and the drain electrode 175 may each include, for example, an aluminum-based metal, such as aluminum (Al) or an aluminum alloy, a silver-based metal, such as silver (Ag) or a silver alloy, a copper-based metal, such as copper (Cu) or a copper alloy including copper manganese (CuMn), a molybdenum-based metal, such as molybdenum (Mo) or a molybdenum alloy, chromium (Cr), tantalum (Ta), tungsten (W) and titanium (Ti).

In the present exemplary embodiment, the source electrode 173 and the drain electrode 175 are each formed as a single layer, but the source electrode 173 and the drain electrode 175 are not limited thereto. For example, alternatively, in an exemplary embodiment, the source electrode 173 and the drain electrode 175 may be formed in the form of a dual layer or a triple layer.

For example, when the source electrode 173 and the drain electrode 175 have a dual layer structure, the source electrode 173 and the drain electrode 175 may each be formed of a lower layer and an upper layer, and the lower layer may be formed of one selected from a molybdenum-based metal, such as molybdenum (Mo) and a molybdenum alloy, chromium (Cr), a chromium alloy, titanium (Ti), a titanium alloy, tantalum (Ta), and a tantalum alloy, manganese (Mn), and a manganese alloy. The upper layer may be formed of, for example, one selected from an aluminum-based metal, such as aluminum (Al) and an aluminum alloy, a silver-based metal, such as silver (Ag) and a silver alloy, a copper-based metal, such as copper (Cu) and a copper alloy. When the source electrode 173 and the drain electrode 175 each have a triple layer structure, the source electrode 173 and the drain electrode 175 may each be formed by, for example, combining layers having different physical properties.

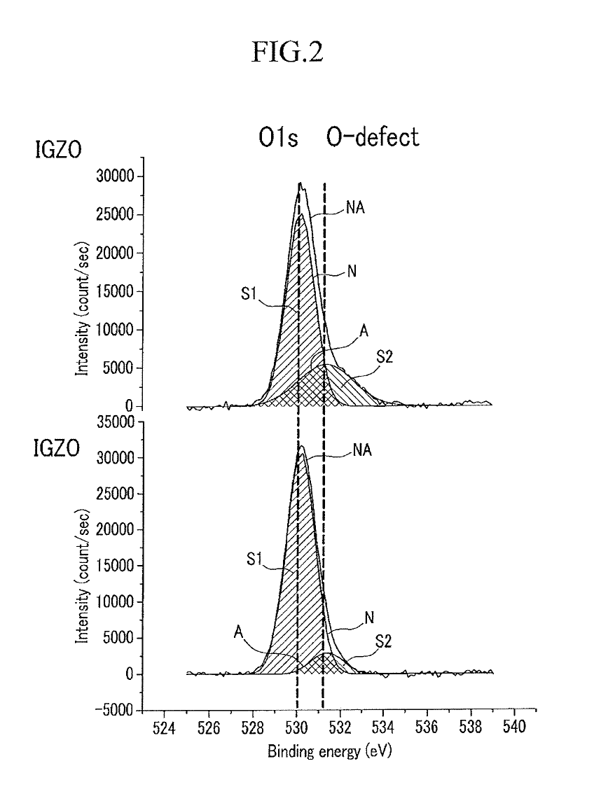

Hereinafter, the oxide semiconductor according to the present exemplary embodiment of the present invention will be described in detail with reference to FIGS. 2 to 4.

FIG. 2 is O1s orbital spectra of X-ray photoelectron spectroscopy (XPS) obtained by measuring oxygen content and oxygen defect content included in an oxide semiconductor. In FIG. 2, a horizontal factor represents binding energy, and a vertical factor represents intensity. Here, the intensity is the number of counting representing a quantity of included oxygen having binding energy that is the horizontal factor.

FIG. 2 may illustrate a defect of oxygen included in the oxide semiconductor. FIG. 2 is a graph of the measurement of binding energy of an 1s orbital of oxygen included in the oxide semiconductor by using X-ray photoelectron spectroscopy (XPS). Particularly, FIG. 2 is a graph of the measurement of binding energy of an electron positioned in the 1s orbital of the oxygen. The binding energy of the oxygen to be described below indicates binding energy of an electron positioned in the 1s orbital of oxygen.

Binding energy O1s of oxygen of a perfect structure including no oxygen defect in a binding of a metal and oxygen is measured with one Gaussian peak, but binding energy of oxygen in a binding structure of a metal and oxygen including an oxygen defect is represented with two or more Gaussian peaks. Accordingly, entire spectra are measured as a non-Gaussian peak because the binding energy O1s of the oxygen including the oxygen defect is larger than the binding energy O1s of the oxygen of the perfect structure.

Referring to FIG. 2, two graphs including an upper graph representing Example 1 and a lower graph representing Example 2 are illustrated. Both of Example 1 and Example 2 include two Gaussian curved lines N and A, and a final curved line NA obtained by adding the two Gaussian curved lines forms a non-Gaussian curve. Another Gaussian curved line A positioned at higher binding energy compared to the Gaussian curved line N that is a main factor of a spectrum is represented in a non-Gaussian region for the final curved line NA. Here, a reference peak may be defined as, for example, a center line with respect to which the Gaussian curved line N is substantially bilaterally symmetrical. In the present exemplary embodiment, the reference peak corresponds to a vicinity of about 529.9 eV that is the binding energy between a metal and oxygen.

A degree of mobility of the Gaussian curved line A including the oxygen defect in Example 2 is smaller than that of the Gaussian curved line A of Example 1 based on another Gaussian curved line N, and a distribution area S2 thereof is also small. Accordingly, it can be seen that the final curved line NA of Example 2 represents a peak close to the Gaussian distribution compared to the final curved line NA of Example 1, and the oxygen defect content of Example 1 is larger than that of Example 2.

An integrated area of the curved line A of the non-Gaussian area getting out of the Gaussian peak by using the XPS analysis method means the oxygen defect content, and an integrated area of the 1s orbital spectrum of the oxygen means the entire oxygen content included in the oxide semiconductor, and an oxygen defect ratio may be measured from the two contents.

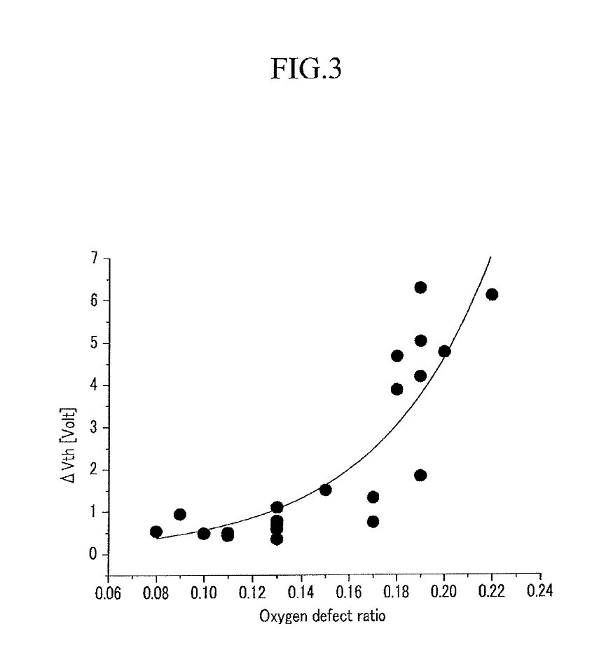

FIG. 3 is a graph of measurement values of positive bias temperature stress (PBTS) according to an oxygen binding ratio, and FIG. 4 is a graph of measurement values of negative bias temperature stress (NBTS) according to an oxygen binding ratio.

Referring to FIG. 3, ΔVth representing a degree of a change in a threshold voltage is increased according to an increase in an oxygen defect ratio according to a measurement result of a value of positive bias temperature stress (PBTS) in terms of reliability. Similarly, referring to FIG. 4, a value of ΔVth representing a degree of a change in a threshold voltage is also increased as a result of measurement of a value of negative bias temperature stress (NBTS) in terms of reliability.

To secure reliability of the thin film transistor, it may be necessary to control the value ΔVth of the positive bias temperature stress (PBTS) representing a degree of the change in the threshold voltage to no greater than about 1.5 V. Accordingly, in the present exemplary embodiment, the defect ratio of the oxygen included in the oxide semiconductor may be set to no greater than about 0.15 by the method described with reference to FIG. 2. Otherwise, to control the value ΔVth of the negative bias temperature stress (NBTS) to no greater than about 0.3 V, the defect ratio of the oxygen included in the oxide semiconductor may be set to no greater than about 0.15 by the method described with reference to FIG. 2.

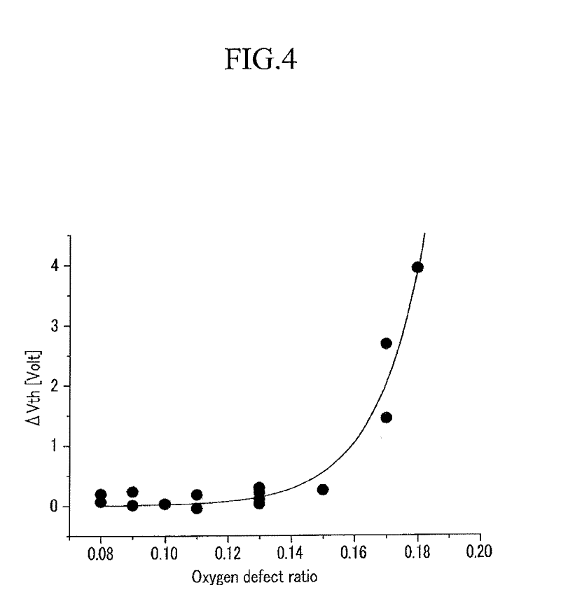

Hereinafter, another reference of determining reliability of the oxide semiconductor will be described with reference to FIGS. 5 to 7.

FIG. 5 is a graph illustrating a change in oxygen defect content included in the oxide semiconductor thin film according to partial pressure of oxygen during a sputtering process.

In FIG. 5, as one example of control of the oxygen defect in the oxide semiconductor, the oxygen defect content included in the oxide semiconductor thin film is changed according to a change in partial pressure of the oxygen of a sputtering method.

Referring to FIG. 5, a tendency that an oxygen defect ratio is increased according to an increase of the partial pressure of oxygen is represented. To decrease a ratio of the oxygen defect, it is significant to minimize the oxygen content included in the oxide semiconductor. In the present exemplary embodiment, to set the ratio of the oxygen defect to no greater than about 0.15, the partial pressure of the oxygen of the sputtering may be set to no greater than about 0.3 Pa.

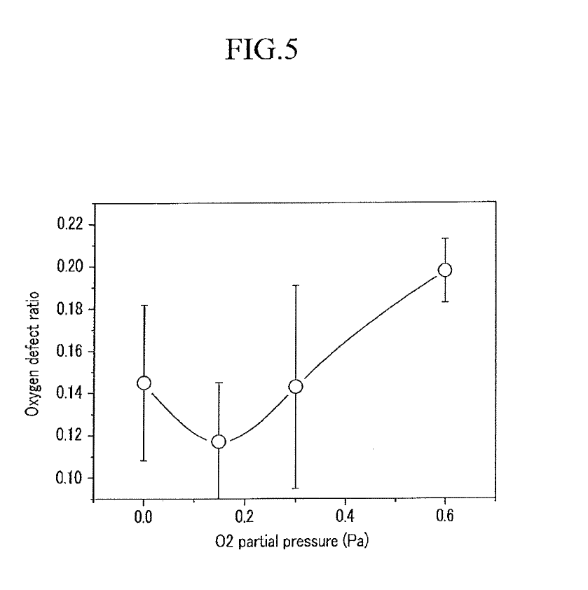

FIG. 6 is a graph illustrating charge mobility of a thin film transistor including the oxide semiconductor according to partial pressure of oxygen of a sputtering process.

Referring to FIG. 6, when the partial pressure of the oxygen of the sputtering process becomes larger than about 0.3 Pa, a characteristic of a device deteriorates in terms of charge mobility of the thin film transistor. Referring to FIGS. 5 and 6, when the ratio of the oxygen defect becomes higher than about 0.15, charge mobility becomes lower than about 4 cm²/Vs, so that a device characteristic may deteriorate. Accordingly, the setting of the ratio of the oxygen defect in the oxide semiconductor included in the thin film transistor according to the present exemplary embodiment of the present invention to no greater than about 0.15 has a meaning as an upper limit of a numerical value range.

In the present exemplary embodiment, the aforementioned partial pressure of the oxygen of about 0.3 Pa may have a different range in which an actual effect is exerted according to process equipment, but the charge mobility and the ratio of the oxygen defect represented according to a result of the effect correspond to unchanged characteristics of a material.

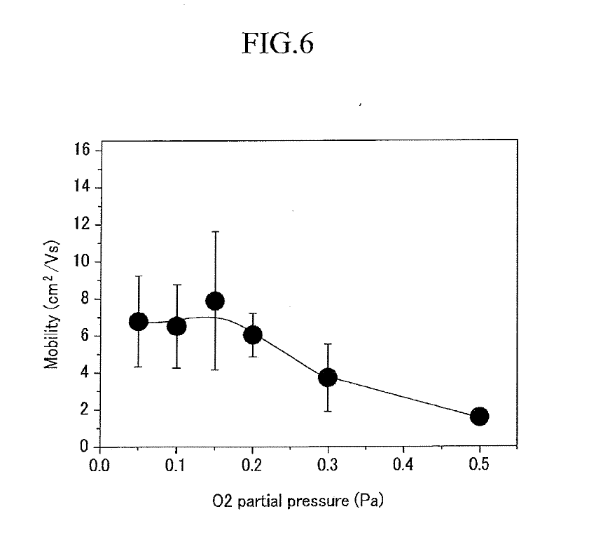

FIG. 7 is a graph illustrating a change in a density of state (DOS) in the oxide semiconductor according to partial pressure of oxygen of a sputtering process.

Referring to FIG. 7, as one example of a control of a DOS in the oxide semiconductor, a DOS within a previously formed oxide semiconductor thin film is changed according to a change in partial pressure of oxygen in a sputtering method.

A semiconductor exhibits an energy band divided into a conduction band and a valence band. The DOS means an energy distribution region positioned between the conduction band and the valence band in the energy band. The DOS illustrated in FIG. 7 means an interface trap with the gate insulating layer in the energy distribution region at a vicinity of the conduction band, and may be defined with a tail state N_{TA} representing a donor characteristic and a deep state N_{DA} representing an acceptor characteristic.

In general, in a case of a perfect material having no defect, the energy distribution, such as the tail state and the deep state, is not generated in the energy band. The tail state N_{TA} and the deep state N_{DA} are the energy distribution showing a fact that the material has a defect.

A C-V method may be used in order to extract the DOS. The C-V method is an analysis method of extracting a capacitance-voltage curved line, and may refer to “Extraction of Subgap Density of States in a-IGZO Thin-Film Transistors by Using Multifrequency Capacitance-Voltage Characteristic,” IEEE Electron Device Letter, vol. 31, no. 3, March 2010, the disclosure of which is hereby incorporated by reference herein in its entirety.

Referring to FIG. 7, a tendency that the DOS in the oxide semiconductor is generally increased according to the increase of the partial pressure of the oxygen during sputtering is presented. The tendency is similar to a relation between the ratio of the oxygen defect and the partial pressure of the oxygen illustrated in FIG. 5. Accordingly, to secure reliability of the thin film transistor, a value of the DOS should be minimized, and in the present exemplary embodiment of the present invention, a reference of a value of the DOS may be defined as a reference for forming the thin film transistor having reliability.

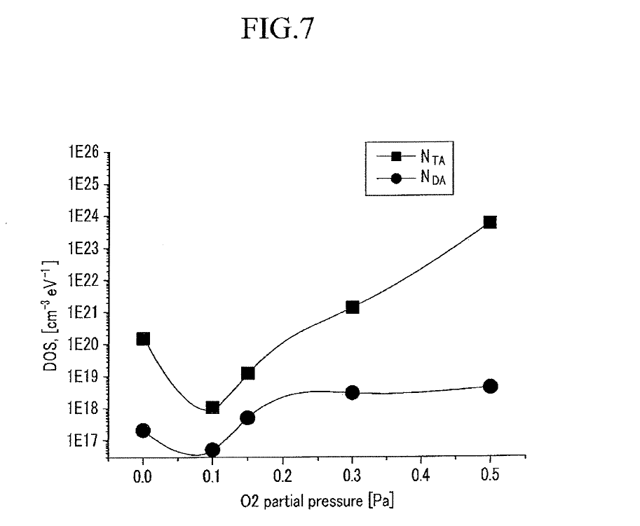

FIG. 8 is a graph of measurement values of positive bias temperature stress according to a tail state.

Referring to FIG. 8, a value of ΔVth representing a degree of a change in a threshold voltage is increased according to an increase of the tail state N_{TA} as a result of measurement of the value of the positive bias temperature stress (PBTS) in terms of reliability.

As illustrated in FIG. 8, after sample A and sample B having the same carrier concentration but having a different tail state N_{TA} are formed, a value of the PBTS is measured. The tail state N_{TA} of sample A is different from the tail state N_{TA} of sample B by approximately 300 times, so that a value of the PBTS of sample A is different from a value of the PBTS of sample B by approximately 10 times. Accordingly, it may be necessary to set the tail state N_{TA} to define a reliability reference of the thin film transistor regardless of a concentration of carrier. To control the value ΔVth of the positive bias temperature stress (PBTS) for securing reliability of the thin film transistor in the oxide semiconductor according to the present exemplary embodiment to be no greater than about 1.5, the tail state N_{TA} may be set to no greater than about 10²¹ cm⁻eV⁻¹, or the deep state may be set to no greater than about 10¹⁸ cm⁻³eV⁻¹.

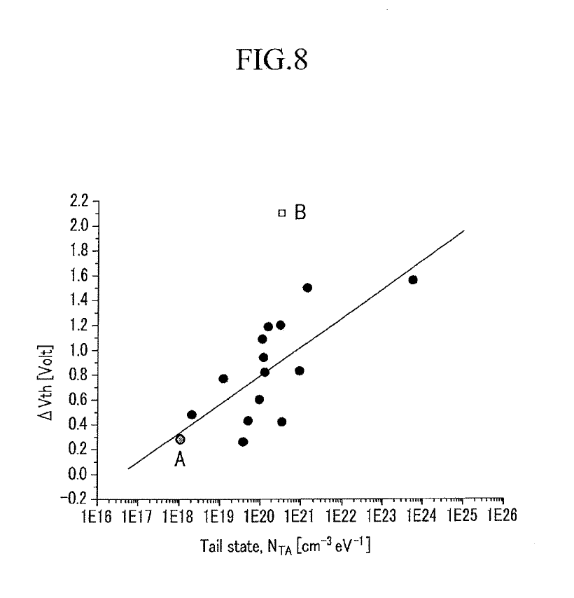

FIG. 9 is a cross-sectional view illustrating a thin film transistor according to an exemplary embodiment of the present invention.

The thin film transistor of FIG. 9 is different from the thin film transistor of FIG. 1 in that the gate electrode 124 is positioned on the oxide semiconductor 154, and the source electrode 173 and the drain electrode 175 are positioned on the substrate 110 under the oxide semiconductor 154. The gate insulating layer 140 is positioned on the substrate 110 so as to cover the source electrode 173 and the drain electrode 175. The description of the thin film transistor of FIG. 1 may be directly applied to a description of a material of each constituent element, the multi layer structure, the oxide semiconductor, and the like for the present exemplary embodiment.

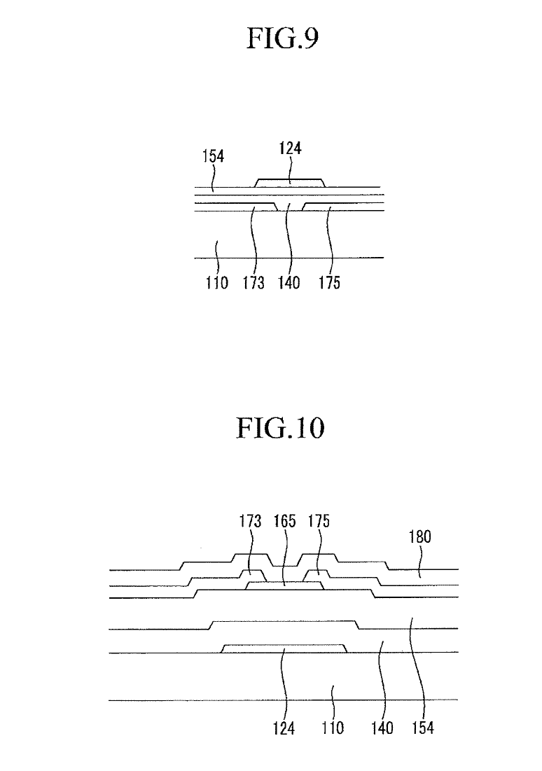

FIG. 10 is a cross-sectional view illustrating a thin film transistor according to an exemplary embodiment of the present invention.

Referring to FIG. 10, this figure illustrates an etch stopper structure, which is different from the thin film transistor of FIG. 1 illustrating a bottom gate structure and the thin film transistor of FIG. 9 illustrating a top gate structure. For example, in the thin film transistor of the present exemplary embodiment, the gate electrode 124 corresponding to a control electrode in the thin film transistor is positioned on the substrate 110, and the gate insulating layer 140 is positioned on the substrate 110 so as to cover the gate electrode 124.

An etching preventing layer 165 is positioned at a position corresponding to a channel region of the semiconductor layer 154. A source electrode 173 and a drain electrode 175 are positioned on the semiconductor layer 154 while being spaced apart from each other so as to overlap an edge of the etching preventing layer 165. The etching preventing layer 165 may be partially exposed at a position at which the source electrode 173 and the drain electrode 175 are spaced apart from each other. The etching preventing layer 165 may be formed of, for example, a silicon-based oxide or a nitride.

A passivation layer 180 is positioned on the source electrode 173 and the drain electrode 175. The passivation layer 180 fills a space in which the source electrode 173 and the drain electrode 175 are spaced apart from each other. In addition, the passivation layer 180 is formed so as to cover the etching preventing layer 165 exposed through the space in which the source electrode 173 and the drain electrode 175 are spaced apart from each other. The passivation layer 180 may be formed of, for example, an inorganic insulator such as silicon oxide (SiOx), silicon nitride (SiNx), silicon oxynitride (SiONx), or any combination thereof. Although it is not illustrated, an organic layer may be formed on the passivation layer 180.

The description of the thin film transistor of FIG. 1 may be directly applied to a description of a material of each constituent element, the multi layer structure, the oxide semiconductor, and the like for the present exemplary embodiment.

As described above, to use the oxide semiconductor as an active layer, that is as a semiconductor layer, of the thin film transistor, the conductivity of the oxide semiconductor is significant. In addition, the oxide semiconductor is also significant for securing the reliability of the thin film transistor. In the present exemplary embodiment, it is possible to form a thin film transistor having reliability by setting a reference of a ratio of a defect of oxygen included in an oxide semiconductor.

Having described the exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. A thin film transistor, comprising:
an oxide semiconductor,
wherein an oxygen defect content of the oxide semiconductor is no greater than about 0.15 based on an entire oxygen content included in the oxide semiconductor.

2. The thin film transistor of claim 1, wherein a ratio of oxygen content to the oxygen defect content in the oxide semiconductor is quantified by measuring binding energy of an 1s orbital of oxygen.

3. The thin film transistor of claim 2, wherein the oxide semiconductor includes at least one of selected from the group consisting of zinc oxide, zinc-tin oxide, zinc-indium oxide, indium oxide, titanium oxide, indium-gallium-zinc oxide, and indium-zinc-tin oxide.

4. The thin film transistor of claim 1, further comprising:
a substrate;
a gate electrode disposed on the substrate;
a source electrode disposed on the substrate; and
a drain electrode disposed on a same layer as that of the source electrode, and facing the source electrode,
wherein the oxide semiconductor is disposed between the gate electrode and the source electrode, or between the gate electrode and the drain electrode.

5. The thin film transistor of claim 4, wherein the gate electrode is disposed under the oxide semiconductor, and the source electrode and the drain electrode are disposed on the oxide semiconductor.

6. The thin film transistor of claim 5, further comprising:
an etching preventing layer covering a channel portion of the oxide semiconductor, and overlapping edges of side surfaces of the source electrode and the drain electrode facing each other.

7. The thin film transistor of claim 6, further comprising:
an insulation layer disposed on the source electrode and the drain electrode, and covering an exposed upper surface of the etching preventing layer between the source electrode and the drain electrode.

8. The thin film transistor of claim 7, wherein the etching preventing layer includes at least one of a silicon-based oxide or a nitride.

9. The thin film transistor of claim 8, wherein the insulating layer includes at least one of silicon oxide (SiOx), silicon nitride (SiNx), and silicon oxynitride (SiONx).

10. The thin film transistor of claim 4, wherein the gate electrode is disposed on the oxide semiconductor, and the source electrode and the drain electrode are disposed under the oxide semiconductor.

11. The thin film transistor of claim 4, further comprising:
an etching preventing layer disposed directly on a channel portion of the oxide semiconductor, wherein a portion of the etching preventing layer is exposed by the source electrode and the drain electrode spaced apart from the source electrode, and wherein the etching preventing layer is in direct physical contact with edges of the source electrode and the drain electrode; and
a passivation layer disposed directly on the source electrode, the drain electrode and the portion of the etching preventing layer exposed by the source electrode and the drain electrode.

12. A thin film transistor, comprising:
an oxide semiconductor,
wherein a tail state in an interface trap at a vicinity of a conduction band of the oxide semiconductor is no greater than about 10²¹ cm⁻³eV⁻¹, and a deep state in the interface trap at the vicinity of the conduction band of the oxide semiconductor is no greater than about 10¹⁸ cm⁻³eV⁻¹.

13. The thin film transistor of claim 12, wherein the oxide semiconductor includes at least one selected from the group consisting of zinc oxide, zinc-tin oxide, zinc-indium oxide, indium oxide, titanium oxide, indium-gallium-zinc oxide, and indium-zinc-tin oxide.

14. The thin film transistor of claim 12, further comprising:
a gate electrode;
a source electrode; and
a drain electrode disposed on a same layer as that of the source electrode, and facing the source electrode,
wherein the oxide semiconductor is disposed between the gate electrode and the source electrode, or between the gate electrode and the drain electrode.

15. The thin film transistor of claim 14, wherein the gate electrode is disposed under the oxide semiconductor, and the source electrode and the drain electrode are disposed on the oxide semiconductor.

16. The thin film transistor of claim 15, further comprising:
an etching preventing layer covering a channel portion of the oxide semiconductor, and overlapping edges of side surfaces of the source electrode and the drain electrode facing each other.

17. The thin film transistor of claim 16, further comprising:
an insulation layer disposed on the source electrode and the drain electrode, and covering an exposed upper surface of the etching preventing layer between the source electrode and the drain electrode.

18. The thin film transistor of claim 17, wherein the etching preventing layer includes at least one of a silicon-based oxide or a nitride.

19. The thin film transistor of claim 14, wherein the gate electrode is disposed on the oxide semiconductor, and the source electrode and the drain electrode are disposed under the oxide semiconductor.

20. The thin film transistor of claim 14, further comprising:
an etching preventing layer disposed directly on a channel portion of the oxide semiconductor, wherein a portion of the etching preventing layer is exposed by the source electrode and the drain electrode spaced apart from the source electrode, and wherein the etching preventing layer is in direct physical contact with edges of the source electrode and the drain electrode; and
a passivation layer disposed directly on the source electrode, the drain electrode and the portion of the etching preventing layer exposed by the source electrode and the drain electrode.
